(19) United States
(12) Patent Application Publication
(10) Pub. No.: US 2026/0107748 A1
(43) Pub. Date: Apr. 16, 2026

(54) FORMING METHOD OF SEMICONDUCTOR STRUCTURE

(71) Applicant: NANYA TECHNOLOGY CORPORATION, New Taipei City (TW)

(72) Inventor: Yu-Tang CHEN, New Taipei City (TW)

(21) Appl. No.: 18/914,292

(22) Filed: Oct. 14, 2024

(51) Int. Cl. H01L 21/768; H01L 21/311

(52) U.S. Cl. CPC H10W 20/056; H10D 1/68; H10P 50/73; H10W 20/062; H10W 20/081

(57) ABSTRACT

The present disclosure provides a method of forming a semiconductor structure. The method includes the following operations. A first hard mask stack is formed on a dielectric layer, in which the dielectric layer includes an array region. The first hard mask stack is etched to form a second hard mask stack and a first trench extending along a first direction above the array region and in the second hard mask stack. A second trench is formed in the second hard mask stack extending along a second direction different from the first direction, in which the first trench and the second trench cross each other to form an intersection. The second hard mask stack and the dielectric layer directly below the intersection are etched to form a through-hole. A first landing pad is formed in the through-hole.

### BACKGROUND

### FIELD OF INVENTION

The present disclosure relates to a forming method of a semiconductor structure.

### DESCRIPTION OF RELATED ART

To pursue lower costs, higher efficiencies, and higher component densities, smaller sizes of the semiconductor structures and components are prevalent. However the decrease of the semiconductor structures and components has increased the difficulties and complexity of the forming process of the semiconductor structure. Therefore, it is a challenge to form a reliability and integrity of the semiconductor structures at smaller sizes.

### SUMMARY

The present disclosure provides a method of forming a semiconductor structure. The method includes the following operations. A first hard mask stack is formed on a dielectric layer, in which the first hard mask stack includes a plurality of carbon layers and a plurality of anti-reflection coating layers that are alternatively stacked, and the dielectric layer includes an array region. The first hard mask stack is etched to form a second hard mask stack and a first trench extending along a first direction above the array region and in the second hard mask stack, in which a bottom surface of the first trench is in one of the anti-reflection coating layers. A photoresist is formed on the second hard mask stack and in the first trench. The photoresist and the second hard mask stack are etched to form a second trench extending along a second direction different from the first direction, in which the first trench and the second trench cross each other to form an intersection. The photoresist is removed. The second hard mask stack directly below the intersection is etched to form a hole to expose the dielectric layer. The dielectric layer exposed from the hole is etched to form a first through-hole. A first landing pad is formed in the through-hole.

In some embodiments, a k value of the dielectric layer is less than or equal to 4.

In some embodiments, forming the first hard mask stack on the dielectric layer includes sequentially depositing a first carbon layer, a first anti-reflection coating layer, a second carbon layer, and a second anti-reflection coating layer on the dielectric layer.

In some embodiments, the bottom surface of the first trench is in the first anti-reflection coating layer.

In some embodiments, forming the photoresist on the second hard mask stack and in the first trench includes sequentially depositing a photoresist underlayer, an anti-reflection structure, and a photoresist layer on the second hard mask stack and in the first trench.

In some embodiments, an angle between the first direction and the second direction is between 60 degrees to 120 degrees.

In some embodiments, forming the first landing pad in the first through-hole includes the following operations. A metal layer is deposited in the first through-hole and on the dielectric layer. The metal layer is planarized to form the first landing pad in the first through-hole.

In some embodiments, the method further includes the following operation. After the first landing pad is formed in the first through-hole, a capacitor structure is formed on the first landing pad.

In some embodiments, after etching the dielectric layer exposed from the hole to form the first through-hole, the method further includes the following operations. A periphery region of the dielectric layer is etched to form a second through-hole. A second landing pad is formed in the second through-hole.

In some embodiments, forming the first landing pad in the first through-hole and forming the second landing pad in the second through-hole are performed simultaneously.

The present disclosure provides a method of forming a semiconductor structure. The method includes the following operations. A first hard mask layer, a second hard mask layer, a third hard mask layer, and a fourth hard mask layer are sequentially deposited on a dielectric layer, in which the first hard mask layer and the third hard mask layer have a high etching selectivity with respect to the second hard mask layer and the fourth hard mask layer, and the dielectric layer includes an array region. The second hard mask layer, the third hard mask layer, and the fourth hard mask layer are etched to form a first trench extending along a first direction above the array region and to remove the third hard mask layer and the fourth hard mask layer. A second trench is formed in the second hard mask layer extending along a second direction different from the first direction, in which the first trench and the second trench cross each other to form an intersection and to expose the first hard mask layer. A first through-hole penetrating the first hard mask layer and the dielectric layer is formed below the intersection. The first hard mask layer and the second hard mask layer are removed. A first landing pad is formed in the first through-hole.

In some embodiments, the first hard mask layer and the third hard mask layer are carbon layers, and the second hard mask layer and the fourth hard mask layer are anti-reflection coating layers.

In some embodiments, the method further includes the following operation. After the first landing pad is formed in the first through-hole, a capacitor structure is formed on the first landing pad.

In some embodiments, before etching the second hard mask layer, the third hard mask layer, and the fourth hard mask layer to form the first trench extending along the first direction above the array region and to remove the third hard mask layer and the fourth hard mask layer, the method further includes the following operations. A patterned photoresist layer with a first opening is formed on the fourth hard mask layer and to expose the fourth hard mask layer. A spacer layer is conformally formed to cover the patterned photoresist layer and in the first opening. A horizontal portion of the spacer layer is etched to expose the patterned photoresist layer and the fourth hard mask layer.

In some embodiments, after removing the first hard mask layer and the second hard mask layer, the method further includes the following operations. A periphery region of the dielectric layer is etched to form a second through-hole. A second landing pad is formed in the second through-hole.

It is to be understood that both the foregoing general description and the following detailed description are by examples, and are intended to provide further explanation of the disclosure as claimed.

### BRIEF DESCRIPTION OF THE DRAWINGS

The present disclosure can be more fully understood by reading the following detailed description of the embodiment, with reference made to the accompanying drawings.

FIG. 1 is a cross-sectional view of a semiconductor structure, in accordance with some embodiments.

FIGS. 2A-2B are flow diagrams of a method of forming the semiconductor structure, in accordance with some embodiments.

FIGS. 3A-3C, 3E-3I, 3K-3M, 3O-6 are cross-sectional views illustrating intermediate stages of forming the semiconductor structure according to various embodiments of the present disclosure.

FIG. 3D is a top view of the semiconductor structure of FIG. 3C.

FIG. 3J is a top view of the semiconductor structure of FIG. 3I.

FIG. 3N is a top view of the semiconductor structure of FIG. 3M.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

It is appreciated that although the terms "first", "second", "third", etc., may be used in this document to describe different components, regions, and/or layers, such components, regions, and/or layers shall not be limited by these terms. These terms are used only to distinguish an assembly, part, region, layer, or part from another component, region, or layer. Therefore, the "first element", "component", "region", or "layer" discussed below may be referred to as a second element, component, region, or layer without departing from the teachings herein.

Further, spatially relative terms, such as “above,” “upper,” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure relates to structures made up of different layers. When the terms “on” are used with reference to two different layers (including the substrate), they indicate merely that one layer is on the other layer. These terms do not require the two layers to directly contact each other, and permit other layers to be between the two layers. For example, all layers of the structure can be considered to be “on” the substrate, even though they do not all directly contact the substrate.

The present disclosure relates to a forming method of the semiconductor structure. In the forming method of the semiconductor structure, a hard mask stack having carbon layers and anti-reflection coating layers that are alternatively stacked is formed on the dielectric layer to act as a mask for the subsequent etching process of the dielectric layer. The hard mask stack having the carbon layers and the anti-reflection coating layers that are alternatively stacked can achieve a good pattern migration effect, such that an accurate pattern can be formed in the dielectric layer.

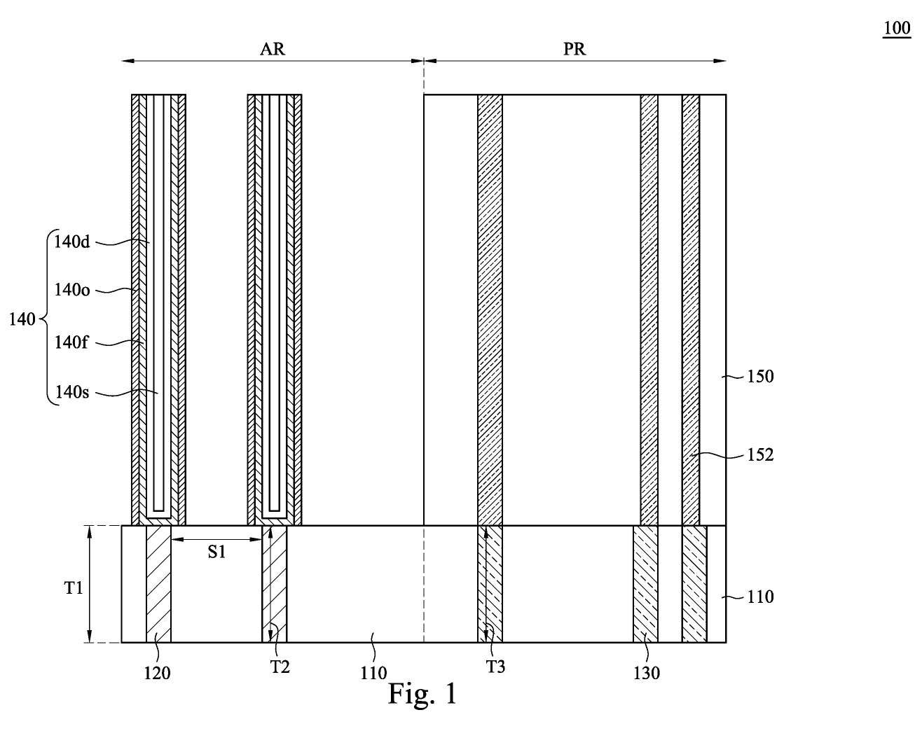

FIG. 1 is a cross-sectional view of a semiconductor structure 100, in accordance with some embodiments. Please refer to FIG. 1. The semiconductor structure 100 includes a dielectric layer 110, first landing pads 120, second landing pads 130, capacitor structures 140, a dielectric layer 150, and conductive lines 152. In some embodiments, the dielectric layer 110 is a low k dielectric layer having a k value less than or equal to 4, such as 1.5, 2, 2.5, 3, 3.5, or 4. In some embodiments, the dielectric layer 110 includes silicon carbide hydroxide (SiCOH), SiLK (Dow Chemical, Midland, Michigan), a flowable oxide, methylsilsesquioxane (MSQ), hydrogen silsesquioxane (HSQ), bis-benzocyclobutene (BCB), fluorosilicate glass (FSG), organosilicate glass (OSG), or combinations thereof, but the present disclosure is not limited thereto. The dielectric layer 110 having the k value less than or equal to 4 may decrease the parasitic capacitance between the first landing pads 120, such that the reliability and integrity of the semiconductor structure 100 may be enhanced. In some embodiments, a thickness T1 of the dielectric layer 110 is between 40 nm and 100 nm, such as 40, 50, 60, 70, 80, 90, or 100 nm.

As shown in FIG. 1, the first landing pads 120 are embedded in an array region AR of the dielectric layer 110. In some embodiments, the first landing pads 120 include metal such as aluminum (Al), tungsten (W), titanium (Ti), tantalum (Ta), gold (Au), silver (Ag), ruthenium (Ru), molybdenum (Mo), or copper (Cu), but the present disclosure is not limited thereto. In some embodiments, a thickness T2 of the first landing pads 120 is between 40 nm and 100 nm, such as 40, 50, 60, 70, 80, 90, or 100 nm. In some embodiments, a spacing S1 between the first landing pads 120 is 10 nm to 20 nm, such as 10, 11, 12, 13, 14, 15, 16, 17, 18, 19, or 20 nm. The spacing S1 between the first landing pads 120 is 10 nm to 20 nm, which may cause small parasitic capacitance between the first landing pads 120 despite the decrease of the dimension of the semiconductor structure, such that the reliability and integrity of the semiconductor structure may be enhanced. In some embodiments, top surfaces of the first landing pads 120 are substantially coplanar with a top surface of the dielectric layer 110. The semiconductor structure 100 may be implemented with any numbers of the first landing pads 120, e.g., one, two, three, four, five, etc.

As shown in FIG. 1, the second landing pads 130 are embedded in a periphery region PR of the dielectric layer 110. In some embodiments, the second landing pads 130 include metal such as Al, W, Ti, Ta, Au, Ag, Ru, Mo, or Cu, but the present disclosure is not limited thereto. In some embodiments, a thickness T3 of the second landing pads 130 is between 40 nm and 100 nm, such as 40, 50, 60, 70, 80, 90, or 100 nm. In some embodiments, top surfaces of the second landing pads 130 are substantially coplanar with a top surface of the dielectric layer 110. The semiconductor structure may be implemented with any numbers of the second landing pads 130, e.g., one, two, three, four, five, etc.

As shown in FIG. 1, the capacitor structures 140 are formed on the array region AR of the dielectric layer 110 and the first landing pads 120. As shown in FIG. 1, the capacitor structures 140 are vertically extend above the first landing pads 120. In some embodiments, a bottom of each capacitor structures 140 is in contact with a top of each first landing pad 120. In some embodiments, the capacitor structures 140 are in a cylinder shape. In some embodiments, each capacitor structures 140 includes outer dielectric layers 140o, a first electrode layer 140f, a capacitor dielectric layer 140d, and a second electrode layer 140s. In some embodiments, the first electrode layers 140f are in contact with the first landing pads 120. In some embodiments, the outer dielectric layers 140o are formed on an outer sidewall of the first electrode layers 140f, and the capacitor dielectric layers 140d are formed conformally on an inner sidewall and bottom of the first electrode layers 140f. In some embodiments, the second electrode layers 140s are formed in the capacitor dielectric layers 140d. In some embodiments, the first electrode layers 140f and the second electrode layers 140s independently include TiN, TaN, Ti, Ta, W, Au, Ag, Mo, Al, or combinations thereof, but the present disclosure is not limited thereto. In some embodiments, the outer dielectric layers 140o and the capacitor dielectric layers 140d independently include zirconium oxide (ZrO₂), titanium oxide (TiO₂), hafnium oxide (HfO₂), silicon dioxide (SiO₂), silicon nitride (Si₃N₄), silicon oxynitride (SiON), or combinations thereof, but the present disclosure is not limited thereto. It is noted that the numbers of the capacitor structures 140 depend on the numbers of the first landing pads 120.

As shown in FIG. 1, the dielectric layer 150 is disposed on the periphery region PR of the dielectric layer 110. In some embodiments, the dielectric layer 150 includes SiO₂, Si₃N₄, SiON, other oxides, other nitrides, or combinations thereof, but the present disclosure is not limited thereto. As shown in FIG. 1, the conductive lines 152 are embedded in the dielectric layer 150. In some embodiments, the conductive lines 152 are in contact with the second landing pads 130. In some embodiments, the conductive lines 152 include metal such as Ti, Ru, Al, W, or Cu, Au, Ag, Mo, but the present disclosure is not limited thereto. In some embodiments, top surfaces of the conductive lines 152 are substantially coplanar with a top surface of the dielectric layer 150. The semiconductor structure 100 may be implemented with any numbers of the conductive lines 152, e.g., one, two, three, four, five, etc.

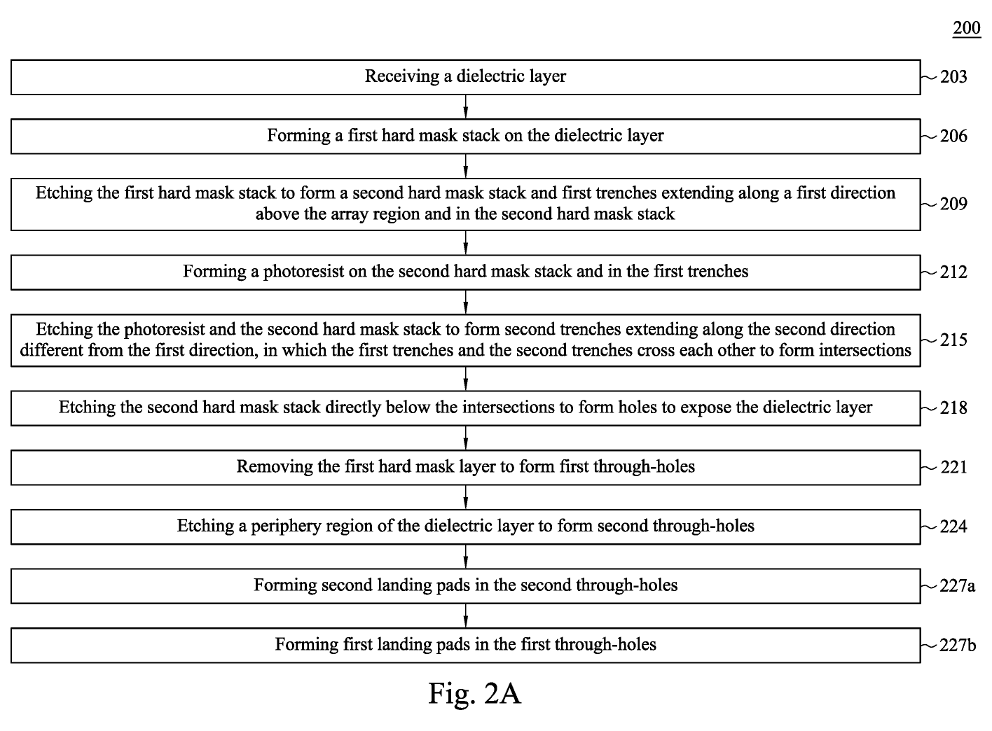

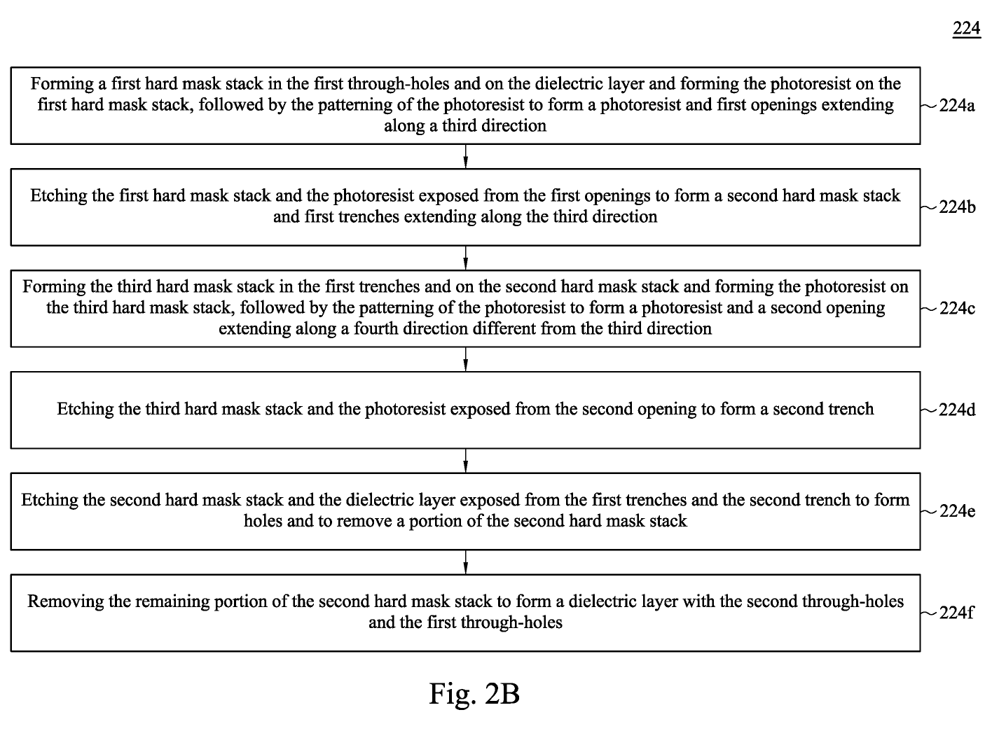

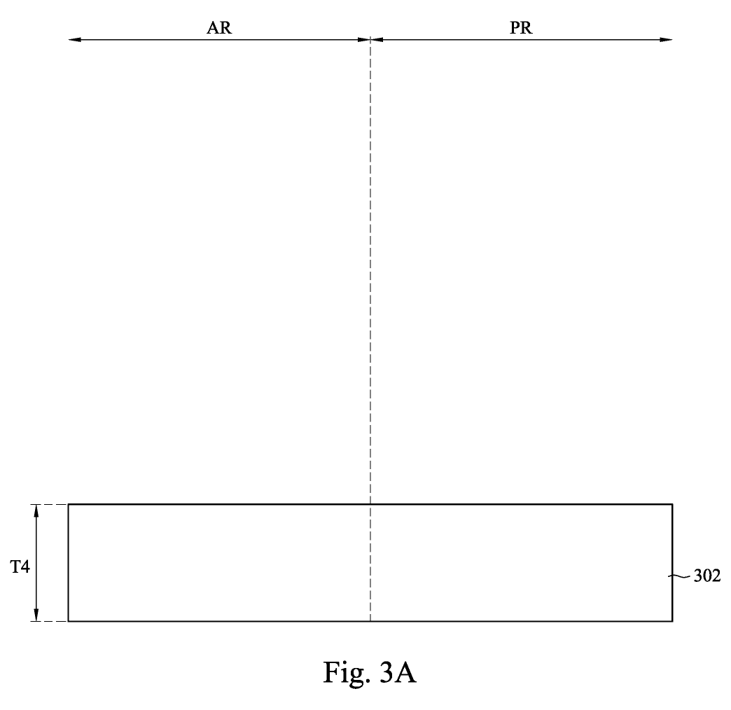

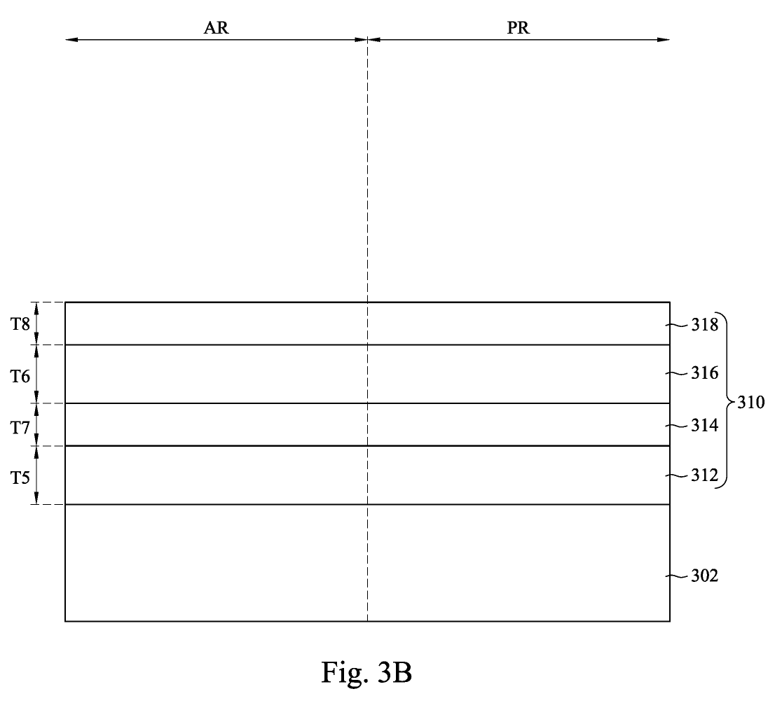

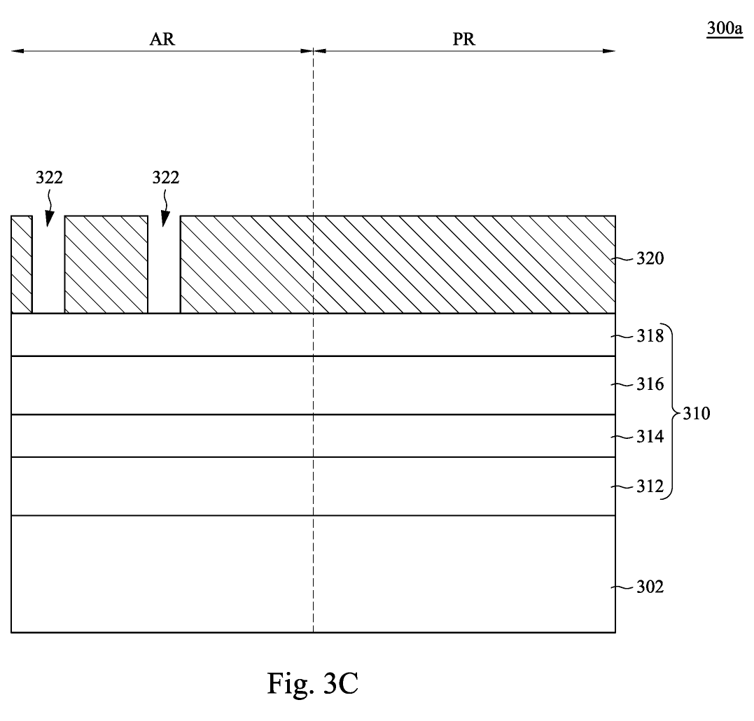

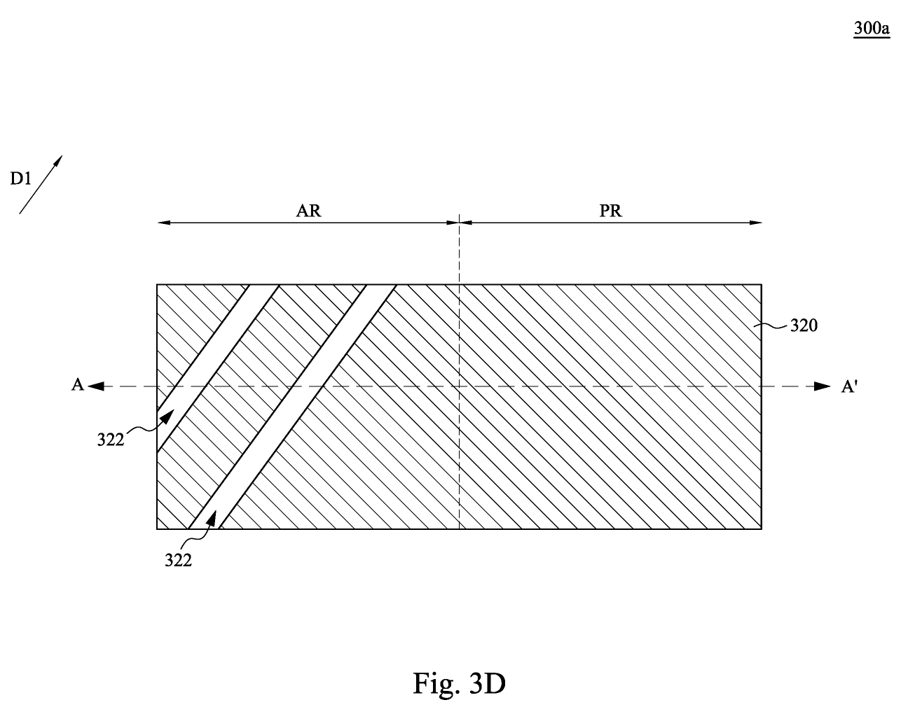

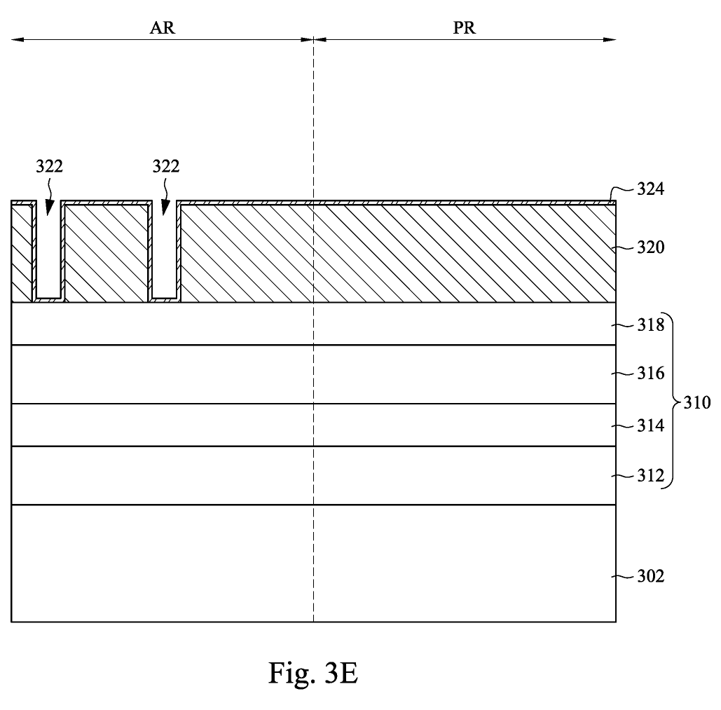

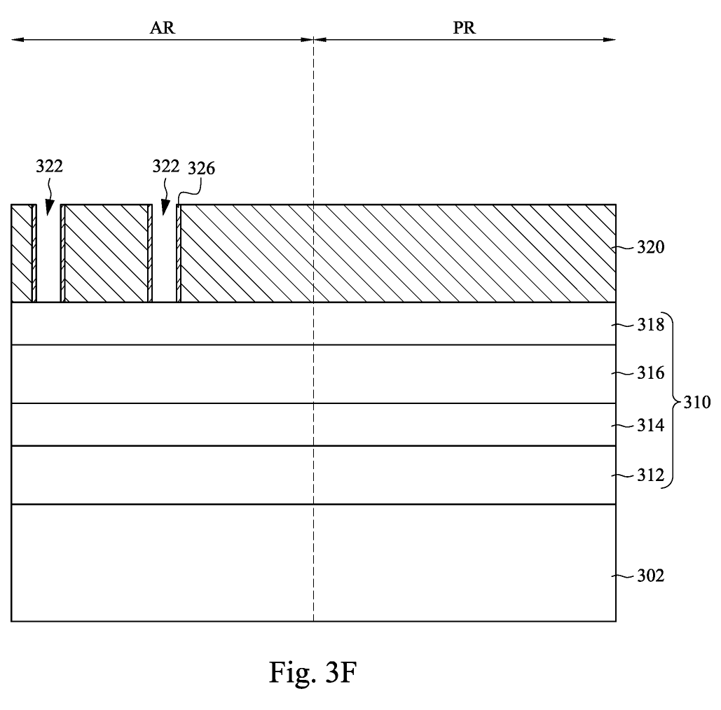

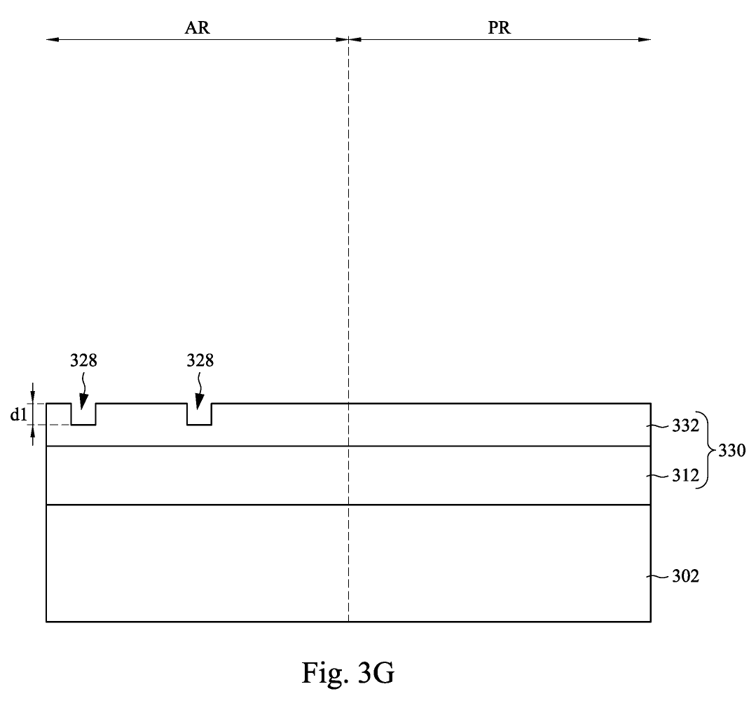

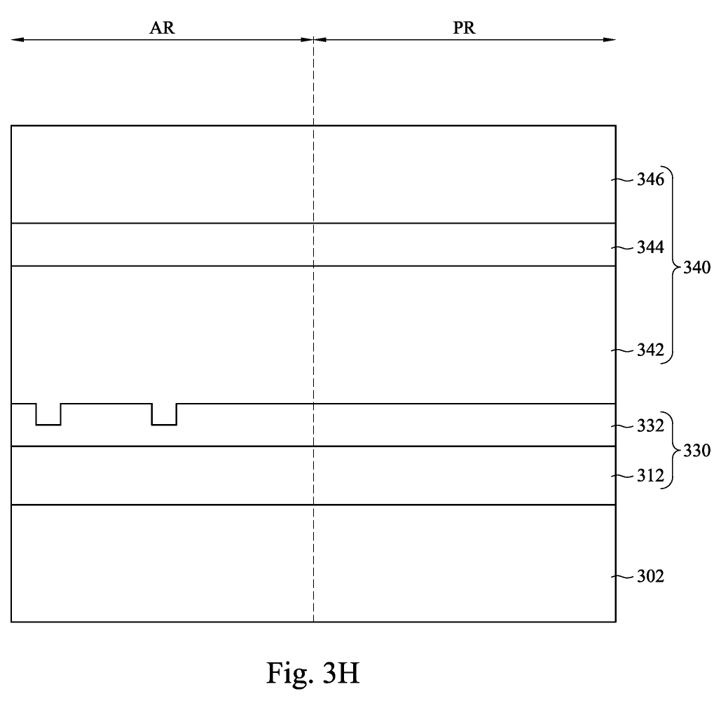

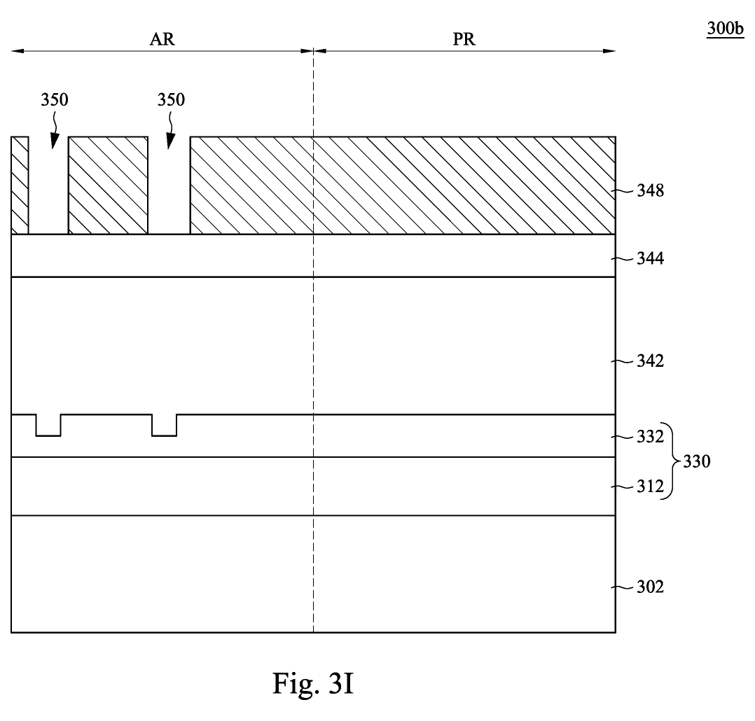

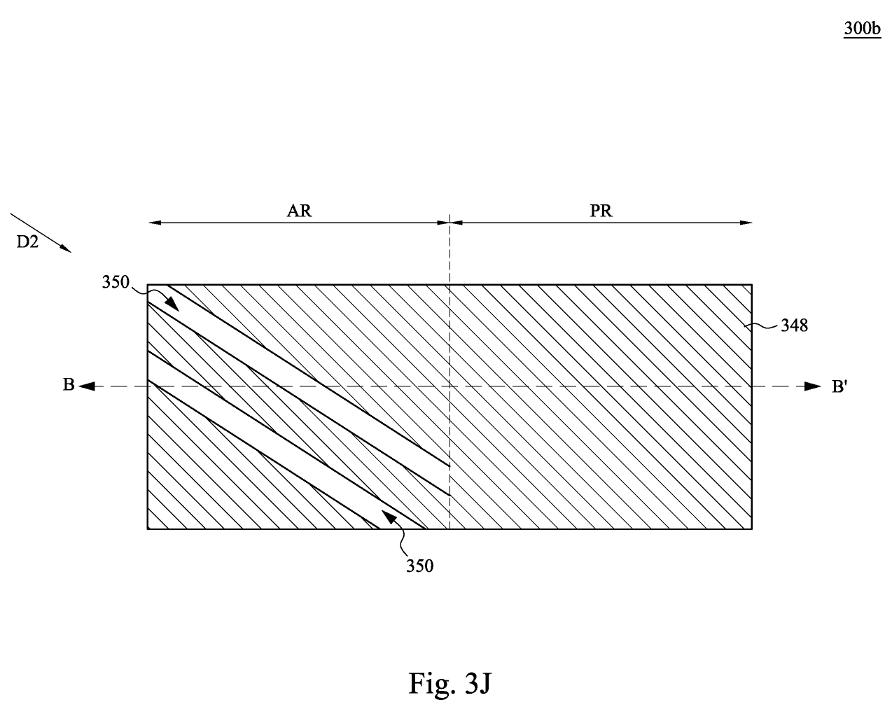

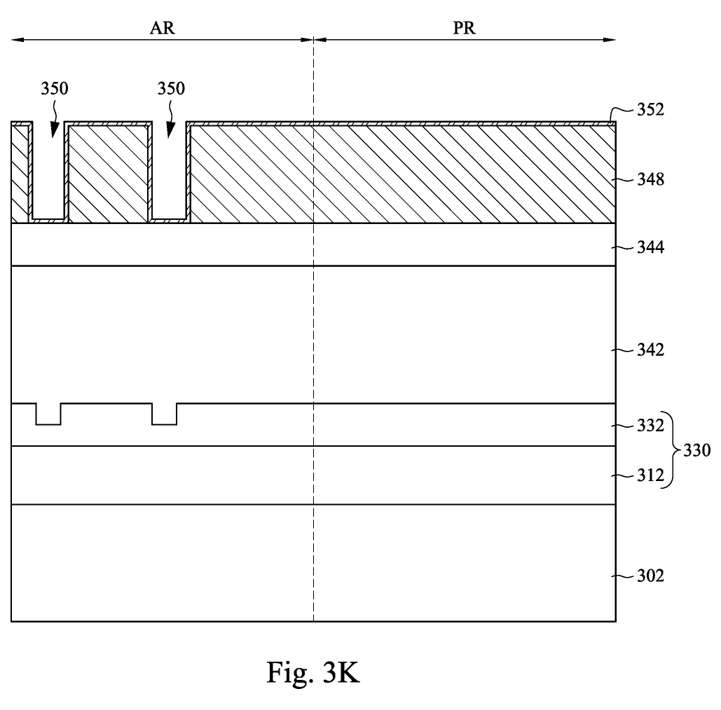

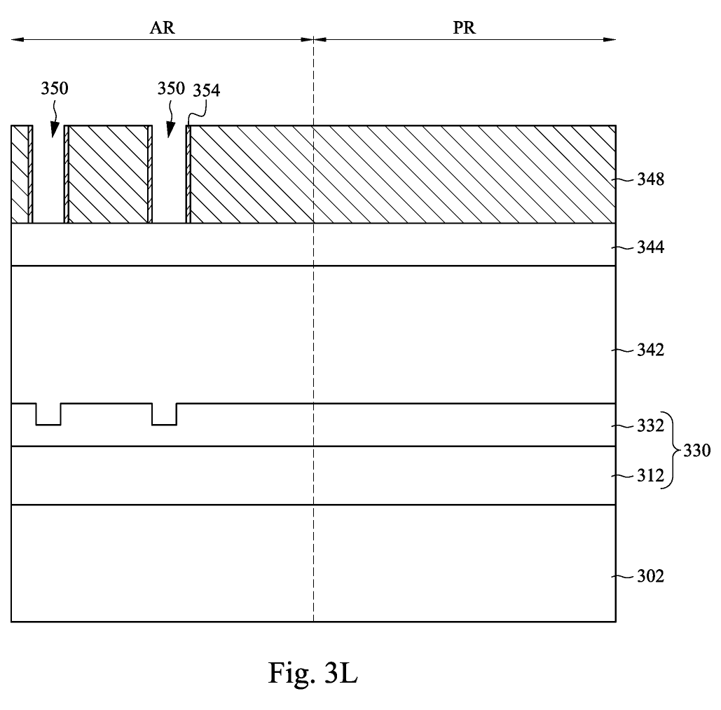

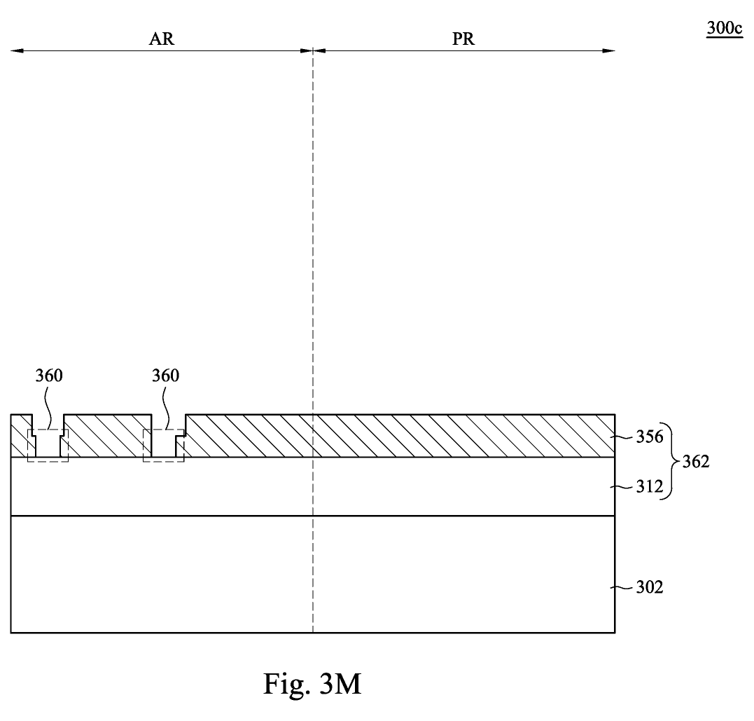

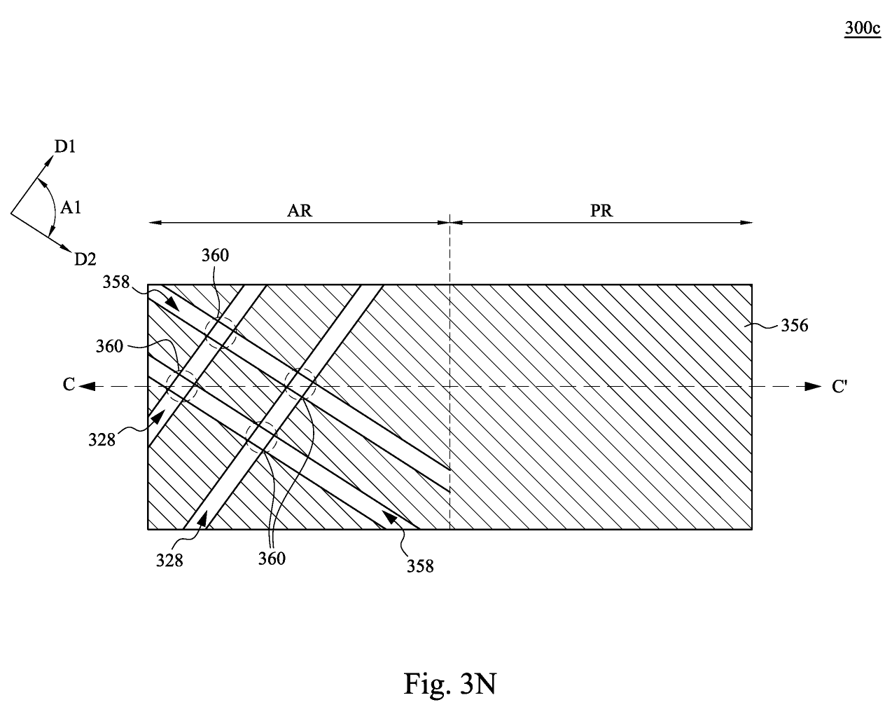

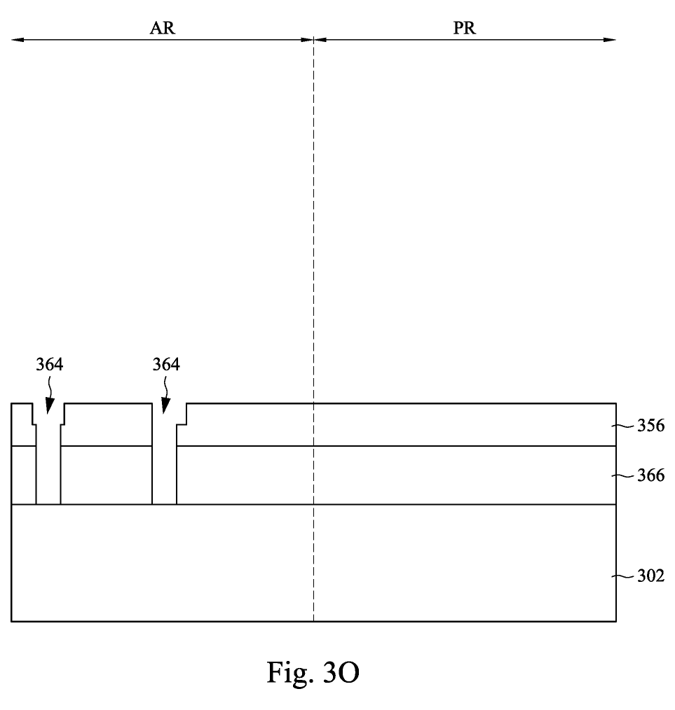

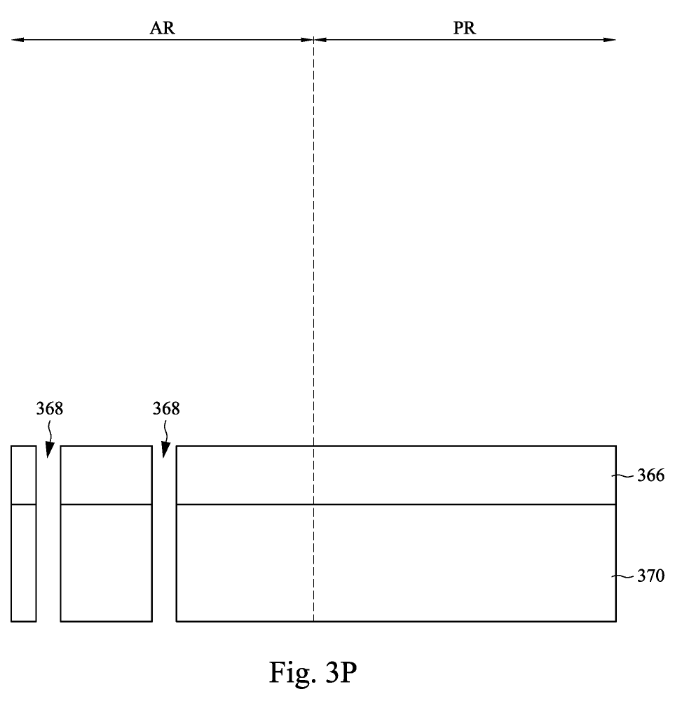

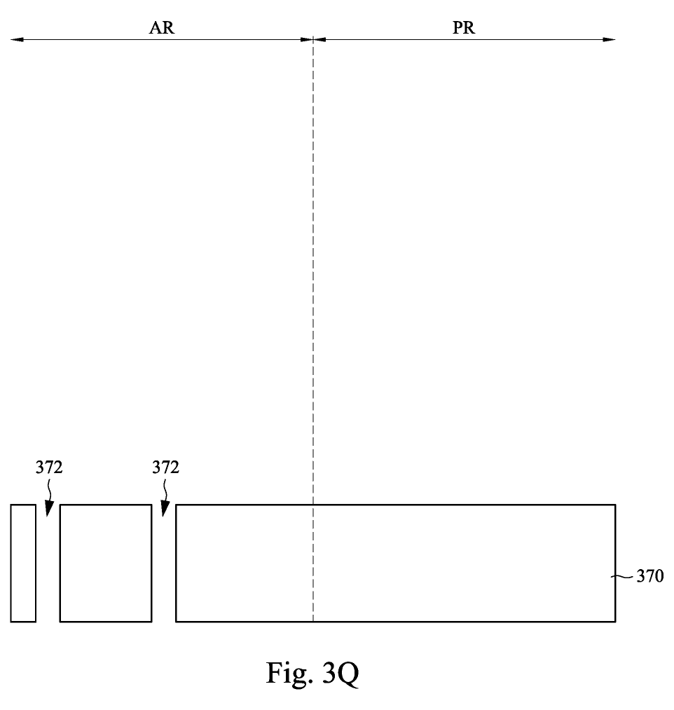

FIGS. 2A-2B are flow diagrams of a method 200 of forming the semiconductor structure 100, in accordance with some embodiments. The method 200 includes operations 203, 206, 209, 212, 215, 218, 221, 224, 227a, and 227b. FIGS. 3A-3C, 3E-3I, 3K-3M, 3O-6 are cross-sectional views illustrating intermediate stages of forming the semiconductor structure 100 according to various embodiments of the present disclosure. Although a series of operations are used below to describe the method 200 disclosed herein, an order of these operations or steps should not be construed as a limitation to the present disclosure. For example, some operations may be performed in a different order, and/or other steps may be performed at the same time. In addition, it is not necessary to perform all of the operations and/or features shown to achieve the embodiments of the present disclosure. In addition, each operations described herein may contain several sub-steps or actions.

Refer to FIGS. 2A and 3A. The method 200 begins with operation 203, a dielectric layer 302 is received. The dielectric layer 302 includes the array region AR and the periphery region PR. In some embodiments, a k value of the dielectric layer 302 is less than or equal to 4, such as 1.5, 2, 2.5, 3, 3.5, or 4. The k value of the dielectric layer 302 less than or equal to 4 may decrease the parasitic capacitance between the first landing pads which is subsequently formed. In some embodiments, a thickness T4 of the dielectric layer 302 is between 40 nm and 100 nm, such as 40, 50, 60, 70, 80, 90, or 100 nm. Refer to FIGS. 2A and 3B. In operation 206, a first hard mask stack 310 is formed on the dielectric layer 302, in which the first hard mask stack 310 includes a plurality of carbon layers and a plurality of anti-reflection coating layers that are alternatively stacked. In some embodiments, the first hard mask stack 310 includes a first hard mask layer 312, a second hard mask layer 314, a third hard mask layer 316, and a fourth hard mask layer 318. The first hard mask layer 312, the second hard mask layer 314, the third hard mask layer 316, and the fourth hard mask layer 318 are sequentially deposited on the dielectric layer 302, in which the first hard mask layer 312 and the third hard mask layer 316 have a high etching selectivity with respect to the second hard mask layer 314 and the fourth hard mask layer 318. That is, the third hard mask layer 316 and the first hard mask layer 312 have a faster etching rate with respect to the fourth hard mask layer 318 and the second hard mask layer 314. In some embodiments, the first hard mask layer 312 has a high etching selectivity with respect to the dielectric layer 302. That is, the first hard mask layer 312 has a faster etching rate with respect to the dielectric layer 302. In some embodiments, a thickness T5 of the first hard mask layer 312 and a thickness T6 of the third hard mask layer 316 are each between 60 nm and 120 nm, such as 60, 70, 80, 90, 100, 110, or 120 nm. In some embodiments, a thickness T7 of the second hard mask layer 314 and a thickness T8 of the fourth hard mask layer 318 are each between 20 nm and 60 nm, such as 20, 25, 30, 35, 40, 45, 50, 55, or 60 nm. In some embodiments, the first hard mask layer 312, the second hard mask layer 314, the third hard mask layer 316, and the fourth hard mask layer 318 are formed by deposition process, such as chemical vapor deposition (CVD) process, physical vapor deposition (PVD) process, atomic layer deposition (ALD) process, low pressure CVD (LPCVD) process, another deposition process, or any suitable combination thereof. In some embodiments, the first hard mask layer 312 and the third hard mask layer 316 include the same materials, such as carbon layers (the first hard mask layer 312 and the third hard mask layer 316 can also be called as a first carbon layer and a second carbon layer, respectively), and the second hard mask layer 314 and the fourth hard mask layer 318 include the same materials, such as anti-reflection coating layers (the second hard mask layer 314 and the fourth hard mask layer 318 can also be called as a first anti-reflection coating layer and a second anti-reflection coating layer, respectively). In some embodiments, the anti-reflection coating layers are dielectric anti-reflection coating (DARC) layers. In some embodiments, the anti-reflection coating layers include SiO₂, SiON, Si₃N₄, combination thereof, or any suitable materials. The second hard mask layer 314 and the fourth hard mask layer 318 include the anti-reflection coating layers may advantageously absorb the light during subsequent light exposure, thereby reduce or minimize light reaching the layers below the second hard mask layer 314 and the fourth hard mask layer 318, and hence reduce the light reflectance from the layers below the second hard mask layer 314 and the fourth hard mask layer 318. Please refer to the aforementioned advantages of the dielectric layer 110 for the advantages of the dielectric layer 302.

FIG. 3C is a cross-sectional view of the semiconductor structure 300a along section line A-A’ in FIG. 3D. FIG. 3D is a top view of the semiconductor structure 300a of FIG. 3C. Refer to FIGS. 2A, 3C, 3D, and 3G. In operation 209, the first hard mask stack 310 is etched to form a second hard mask stack 330 and first trenches 328 extending along a first direction D1 above the array region AR of the dielectric layer 302 and in the second hard mask stack 330, in which a bottom surface of the first trenches 328 is in one of the anti-reflection coating layers. In some embodiments, the second hard mask stack 330 includes the first hard mask layer 312 and the second hard mask layer 332, that is, the second hard mask layer 314, the third hard mask layer 316, and the fourth hard mask layer 318 are etched to form the second hard mask layer 332 and the first trenches 328 extending along the first direction D1 above the array region AR of the dielectric layer 302 and to remove the third hard mask layer 316 and the fourth hard mask layer 318. In some embodiments, the bottom surface of the first trenches 328 are in the second hard mask layer 332 (or the first anti-reflection coating layer). In some embodiments, the bottom surfaces of the first trenches 328 are in a half height of the second hard mask layer 332. In some embodiments, a depth d1 of the first trenches 328 is between 10 nm and 30 nm, such as 10, 15, 20, 25, or 30 nm. In some embodiments, the first hard mask stack 310 is etched by the dry etching process. The detailed etching process of the operation 209 will be described further later.

Refer to FIGS. 2A and 3C-3G. In some embodiments, before the first hard mask stack 310 is etched to form the second hard mask stack 330 and first trenches 328 extending along the first direction D1 above the array region AR of the dielectric layer 302 and in the second hard mask stack 330, the method 200 further includes the following operations. A patterned photoresist layer 320 with first openings 322 is formed on the first hard mask stack 310 and to expose the first hard mask stack 310, as shown in FIG. 3C. In some embodiments, the number of the first openings 322 can be for example one, three, four, five, etc. In some embodiments, the patterned photoresist layer 320 with the first openings 322 is formed on the fourth hard mask layer 318 and to expose the fourth hard mask layer 318, as shown in FIG. 3C. In some embodiments, the patterned photoresist layer 320 is formed by the deposition and patterning of the photoresist (not shown). That is, the photoresist may be deposited and then selectively exposed via a mask (not shown) to visible light, ultraviolet light, or so forth, followed by development of the exposed photoresist, resulting in the patterned photoresist layer 320. In some embodiments, the photoresist is deposited by, for example and without limitation, CVD process, PVD process, ALD process, sputtering, LPCVD process, another deposition process, or any suitable combination thereof. In some embodiments, the first openings 322 are extended along the first direction D1 above the array region AR of the dielectric layer 302, as shown in FIGS. 3C and 3D.

After the patterned photoresist layer 320 with first openings 322 are formed on the first hard mask stack 310 and to expose the first hard mask stack 310, a spacer layer 324 is conformally formed to cover the patterned photoresist layer 320 and in the first opening 322, as shown in FIGS. 3C and 3E. In some embodiments, the spacer layer 324 is formed by deposition process, such as CVD process, PVD process, ALD process, sputtering, LPCVD process, another deposition process, or any suitable combination thereof. In some embodiments, the spacer layer 324 includes materials including silicon (Si) and oxygen (O), such as SiO₂.

After the spacer layer 324 is conformally formed to cover the patterned photoresist layer 320 and in the first opening 322, the horizontal portions of the spacer layer 324 are etched to expose the patterned photoresist layer 320 and the first hard mask stack 310 and to form spacers 326, as shown in FIGS. 3E and 3F. In some embodiments, the horizontal portions of the spacer layer 324 are etched to expose the fourth hard mask layer 318, as shown in FIG. 3F. In some embodiments, the horizontal portions of the spacer layer 324 are etched by dry etching process. In some embodiments, the spacers 326 include vertical portions of the spacer layer 324 and are on the sidewalls of the first openings 322 of the patterned photoresist layer 320. In some embodiments, the spacers 326 and the patterned photoresist layer 320 may serve as an etching mask for subsequent etching of the first hard mask stack 310. The spacers 326 formed on the sidewalls of the first openings 322 of the patterned photoresist layer 320 may reduce the line width roughness of the subsequent formed profile, which further enhance the integrity and the reliability of the semiconductor structure.

As shown in FIGS. 3F and 3G, after the horizontal portions of the spacer layer 324 are etched to expose the patterned photoresist layer 320 and the first hard mask stack 310 and to form the spacers 326, the operation 209 is performed. In some embodiments, the detailed etching process of the operation 209 includes the following operations. The exposed portions of the fourth hard mask layer 318 are etched to form second openings (not shown) to expose the third hard mask layer 316. The third hard mask layer 316 exposed from the second openings are etched, and the patterned photoresist layer 320 are removed to form third openings (not shown) to expose the second hard mask layer 314. The second hard mask layer 314 exposed from the third openings are etched, and the fourth hard mask layer 318 and the spacers 326 are removed to form fourth openings (not shown). The third hard mask layer 316 is removed to form the first trenches 328, as shown in FIG. 3G. In some embodiments, the fourth hard mask layer 318, the third hard mask layer 316, the patterned photoresist layer 320, the second hard mask layer 314, and the spacers 326 are etched or/and removed by an anisotropic etching process (e.g. dry etching process). The third hard mask layer 316 has a high etching selectivity with respect to the fourth hard mask layer 318, which may prevent the pattern of the fourth hard mask layer 318 from damage as the third hard mask layer 316 being etched. Thus, a better pattern migration effect may be achieved, and the pattern will be more accurate, such that the reliability and integrity of the semiconductor structure may be enhanced.

As shown in FIGS. 2A and 3G-3H, in operation 212, a photoresist 340 is formed on the second hard mask stack 330 and in the first trenches 328. In some embodiments, the photoresist 340 is formed on the second hard mask layer 332 and in the first trenches 328. In some embodiments, the photoresist 340 is a tri-layer photoresist. In some embodiments, the photoresist 340 includes a photoresist underlayer 342, an anti-reflection structure 344, and a photoresist layer 346. In some embodiments, forming the photoresist 340 on the second hard mask stack 330 and in the first trenches 328 includes sequentially depositing the photoresist underlayer 342, the anti-reflection structure 344, and the photoresist layer 346 on the second hard mask stack 330 and in the first trenches 328. In some embodiments, the material of the photoresist underlayer 342 and the photoresist layer 346 are similar to the first hard mask layer 312 and the third hard mask layer 316. In some embodiments, the anti-reflection structure 344 is a DARC layer. In some embodiments, the photoresist underlayer 342, the anti-reflection structure 344, and the photoresist layer 346 are deposited by such as CVD process, PVD process, ALD process, sputtering, LPCVD process, another deposition process, or any suitable combination thereof.

FIG. 3I is a cross-sectional view of the semiconductor structure 300b along section line B-B’ in FIG. 3J. FIG. 3J is a top view of the semiconductor structure 300b of FIG. 3I. FIG. 3M is a cross-sectional view of the semiconductor structure 300c along section line C-C’ in FIG. 3N. FIG. 3N is a top view of the semiconductor structure 300c of FIG. 3M. As shown in FIGS. 2A, 3H, 3M, and 3N, in operation 215, the photoresist 340 and the second hard mask stack 330 are etched to form a second hard mask stack 362 and second trenches 358 extending along the second direction D2 different from the first direction D1, in which the first trenches 328 and the second trenches 358 cross each other to form intersections 360. In some embodiments, the second hard mask stack 362 includes the first hard mask layer 312 and a second hard mask layer 356. In some embodiments, the photoresist 340 and the second hard mask layer 332 are etched to form the second hard mask layer 356 and the second trenches 358 extending along the second direction D2 different from the first direction D1, in which the first trenches 328 and the second trenches 358 cross each other to form the intersections 360. In some embodiments, an angle A1 between the first direction D1 and the second direction D2 is between 60 degrees to 120 degrees, such as 60, 70, 80, 90, 100, 110, or 120 degrees, as shown in FIG. 3N. In some embodiments, a depth of the second trenches 358 is same as the depth d1 of the first trenches 328, that is, from 10 nm to 30 nm, such as 10, 15, 20, 25, or 30 nm. In some embodiments, the first hard mask layer 312 is exposed from the intersections 360. In some embodiments, the photoresist 340, the second hard mask stack 330, and the second hard mask layer 332 are etched by the anisotropic etching process (e.g. dry etching process).

As shown in FIGS. 2A and 3H-3N, before operation 215, the method 200 further includes the following operations. The photoresist layer 346 is patterned to form a patterned photoresist layer 348 and first openings 350 extending along the second direction D2, as shown in FIGS. 3H-3J. A spacer layer 352 is conformally formed to cover the patterned photoresist layer 348 and in the first openings 350, as shown in FIGS. 3I and 3K. Horizontal portions of the spacer layer 352 are etched to expose the patterned photoresist layer 348 and the anti-reflection structure 344 and to form spacers 354, as shown in FIGS. 3K-3L. Please refer to the aforementioned embodiments of the patterned photoresist layer 320, the first openings 322, the spacer layer 324, and the spacers 326 for the patterned photoresist layer 348, the first openings 350, the spacer layer 352, and the spacers 354. The detailed etching process of the operation 215 is similar to the detailed etching process of the operation 209. Please refer to the aforementioned embodiments and the advantages of the detailed etching process of the operation 209 for the embodiments and the advantages of the detailed etching process of the operation 215. After operation 215, the photoresist 340 is removed, as shown in FIGS. 3H and 3M.

As shown in FIGS. 2A, 3M, and 3O, in operation 218, the second hard mask stack 362 directly below the intersections 360 are etched to form holes 364 to expose the dielectric layer 302. In some embodiments, the first hard mask layer 312 below the intersections 360 are etched to form a first hard mask layer 366 and the holes 364 to expose the dielectric layer 302, as shown in FIGS. 3M and 3O. In some embodiments, the second hard mask stack 362 and the first hard mask layer 312 directly below the intersections 360 are etched by anisotropic etching process (e.g., dry etching process). The first hard mask layer 312 has a high etching selectivity with respect to the second hard mask layer 356, which may prevent the pattern of the second hard mask layer 356 from damage as the first hard mask layer 312 being etched. Thus, a better pattern migration effect may be achieved, and the pattern will be more accurate, such that the reliability and integrity of the semiconductor structure may be enhanced. As shown in FIGS. 2A, 3O, and 3P, in operation 221, the dielectric layer 302 exposed from the holes 364 is etched to form first through-holes 368 and a dielectric layer 370. In some embodiments, the second hard mask layer 356 is removed during the etching process of the dielectric layer 302 to form the first through-holes 368. In some embodiments, the dielectric layer 302 is etched by anisotropic etching process (e.g., dry etching process). As shown in FIGS. 2A, 3P, and 3Q, after operation 221, the first hard mask layer 366 is removed to form first through-holes 372. In some embodiments, the first hard mask layer 366 is removed by dry etching process, in which the gas used in the dry etching process is O₂. The first hard mask layer 366 has a high etching selectivity with respect to the dielectric layer 370, which may easily remove the first hard mask layer 366 without damaging the dielectric layer 370, such that the reliability and integrity of the semiconductor structure may be enhanced.

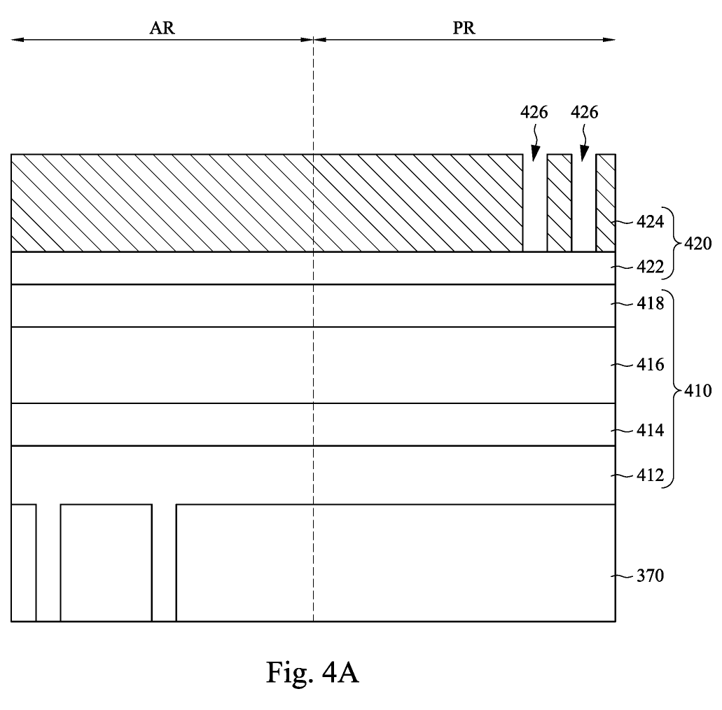

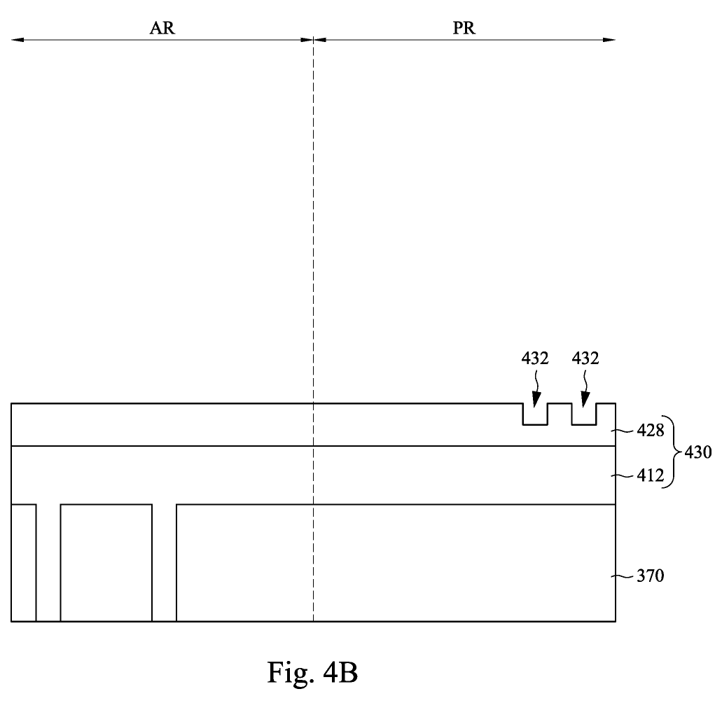

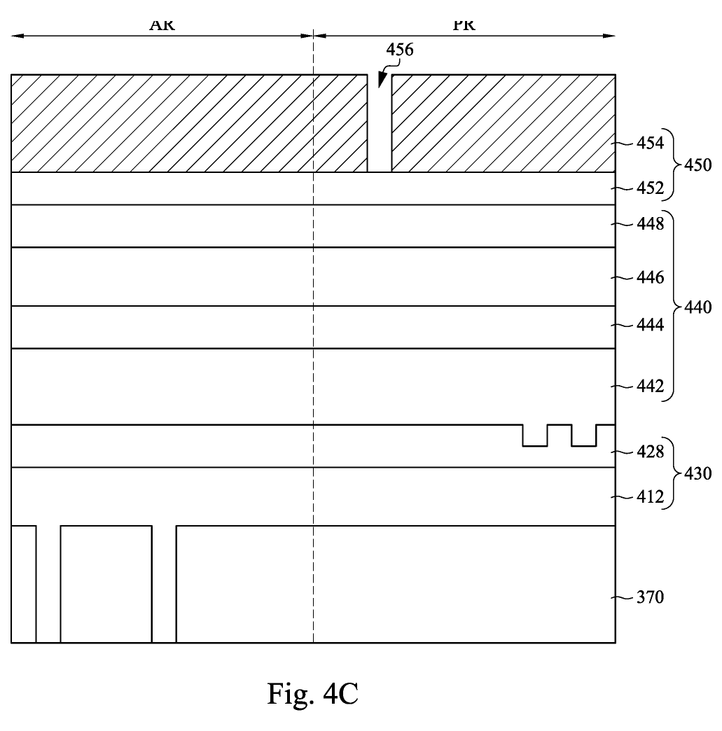

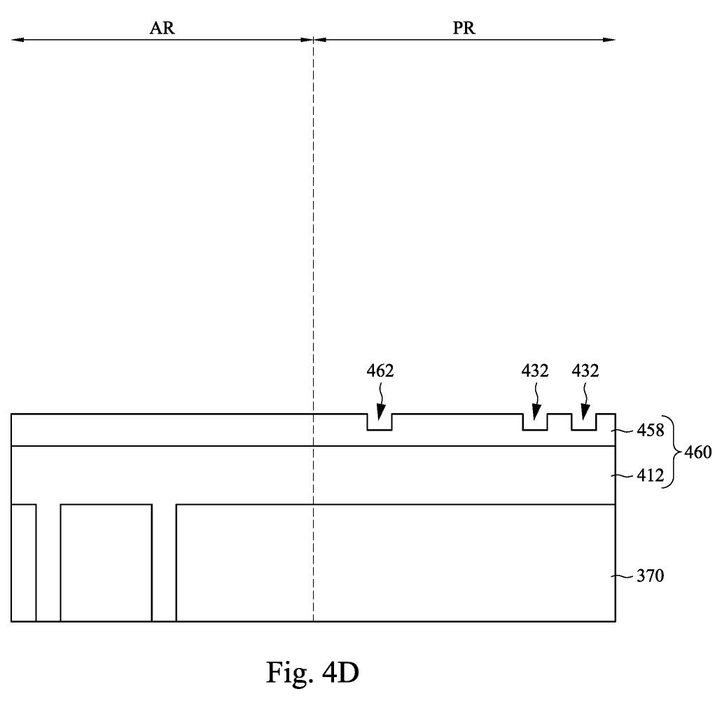

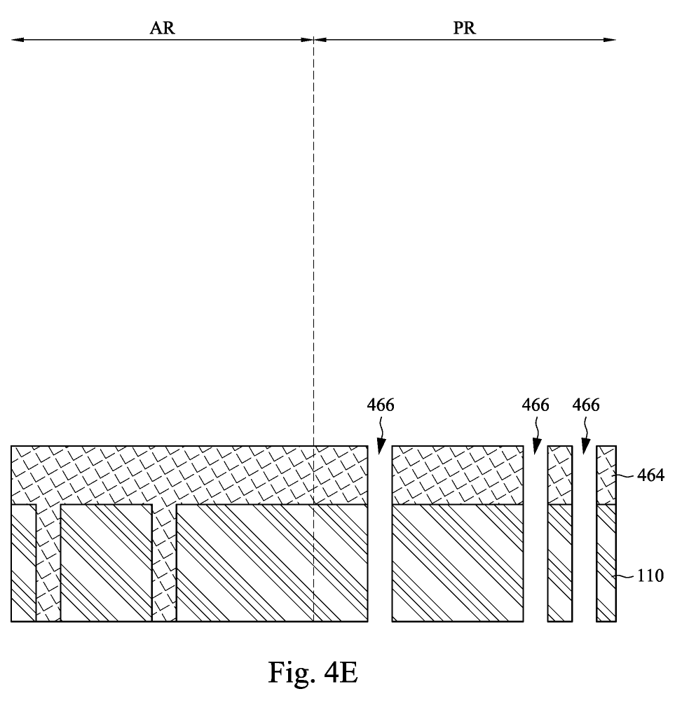

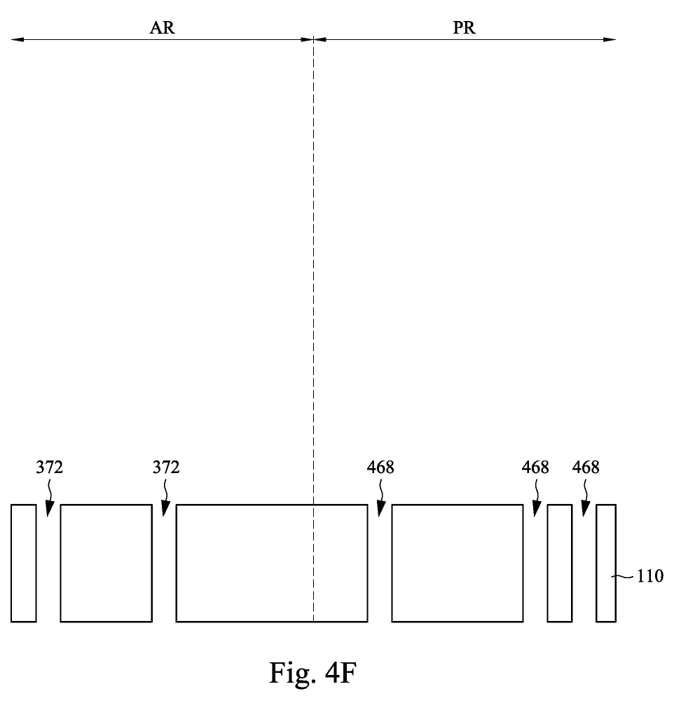

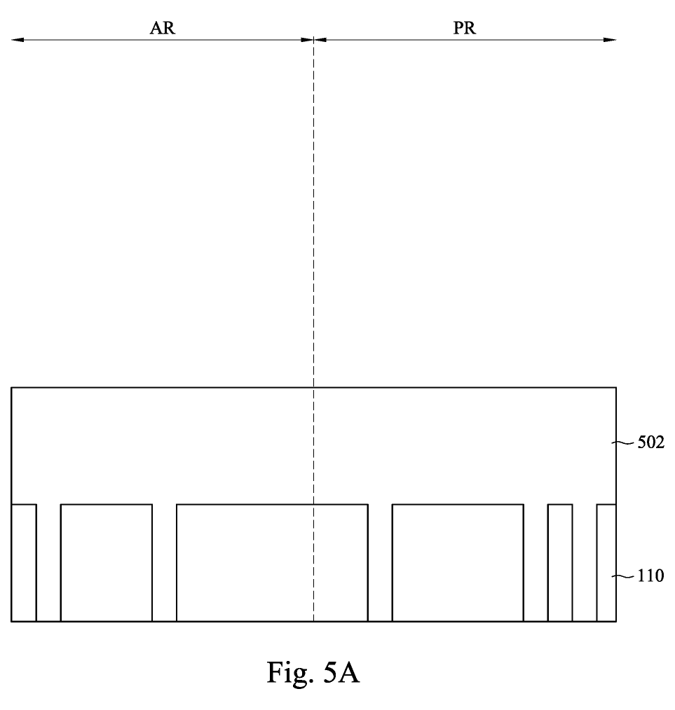

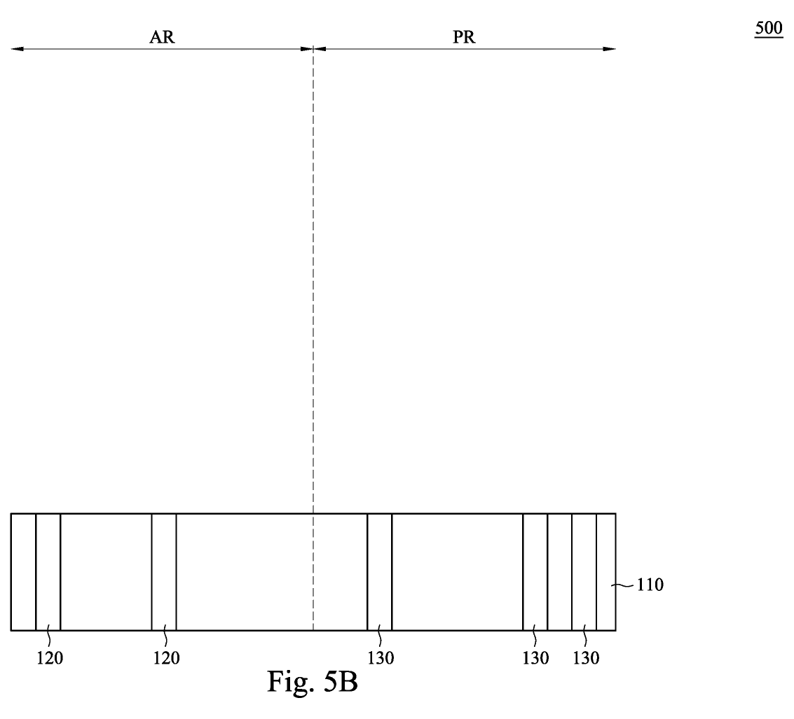

In some embodiments, after etching the dielectric layer 302 exposed from the holes 364 to form the first through-holes 368 (operation 221) and removing the first hard mask layer 366 to form the first through-holes 372, the method 200 further includes the operations 224 and 227a. In operation 224, the periphery region PR of the dielectric layer 370 is etched to form second through-holes 468, as shown in FIGS. 4A-4F. In operation 227a, second landing pads 130 are formed in the second through-holes 468, as shown in FIGS. 5A-5B. Operations 224 and 227a will be further described below.

Refer to FIGS. 2A and 4A-4F, in operation 224, the periphery region PR of the dielectric layer 370 is etched to form the second through-holes 468. In some embodiments, the periphery region PR of the dielectric layer 370 is etched by dry etching process. In some embodiments, operation 224 includes the operations 224a-224f. As shown in FIGS. 2B, 3Q, and 4A, in operation 224a, a first hard mask stack 410 is formed in the first through-holes 372 and on the dielectric layer 370, and the photoresist (not shown) is formed on the first hard mask stack 410, followed by the patterning of the photoresist to form a photoresist 420 and first openings 426 extending along a third direction (not shown). In some embodiments, the first hard mask stack 410 includes a first hard mask layer 412, a second hard mask layer 414, a third hard mask layer 416, and a fourth hard mask layer 418. Please refer to the aforementioned embodiments of the first hard mask layer 312, the second hard mask layer 314, the third hard mask layer 316, and the fourth hard mask layer 318 for the embodiments of the first hard mask layer 412, the second hard mask layer 414, the third hard mask layer 416, and the fourth hard mask layer 418. In some embodiments, the first hard mask layer 412 is deposited in the first through-holes 372. In some embodiments, the fourth hard mask layer 418 includes an oxide-rich DARC having an oxide content of 15 atomic % to 30 atomic %, such as 15, 16, 17, 18, 19, 20, 21, 22, 23, 24, 25, 26, 27, 28, 29, or 30 atomic %. The fourth hard mask layer 418 including the oxide-rich DARC having the oxide content of 15 atomic % to 30 atomic % may advantageously absorb the light during subsequent light exposure, thereby reduce or minimize light reaching the layers below the fourth hard mask layer 418, and hence reduce the light reflectance from the layers below the fourth hard mask layer 418. The other advantages of the fourth hard mask layer 418 will be described below. In some embodiments, the photoresist 420 is a bi-layer photoresist. In some embodiments, the photoresist 420 includes an anti-reflection structure 422 and a photoresist layer 424. In some embodiments, the anti-reflection structure 422 is a bottom anti-reflection coating (BARC) layer. The anti-reflection structure 422 includes the BARC layer may advantageously absorb the light during subsequent light exposure, thereby reduce or minimize light reaching the layers below the anti-reflection structure 422, and hence reduce the light reflectance from the layers below the anti-reflection structure 422. In some embodiments, the photoresist layer (not shown) is patterned to form the first openings 426 to expose the anti-reflection structure 422.

As shown in FIGS. 2B, 4A, and 4B, in operation 224b, the first hard mask stack 410 and the photoresist 420 exposed from the first openings 426 are etched to form a second hard mask stack 430 and first trenches 432 extending along the third direction (not shown). In some embodiments, the second hard mask stack 430 includes the first hard mask layer 412 and a second hard mask layer 428 with the first trenches 432. In some embodiments, the first trenches 432 are in the second hard mask layer 428. In some embodiments, the anti-reflection structure 422 exposed from the first openings 426 are etched to expose the fourth hard mask layer 418. Please refer to the embodiments of the detailed etching process of the operation 209 for the detailed etching process of the first hard mask stack 410. In some embodiments, the second hard mask layer 414 and the fourth hard mask layer 418 are etched by wet etching process. Due to the fourth hard mask layer 418 including the oxide-rich DARC having an oxide content of 15 atomic % to 30 atomic %, the etching selectivity between the fourth hard mask layer 418 and the third hard mask layer 416 enhance, comparing to the fourth hard mask layer 318 and the third hard mask layer 316. This causes during the etching process of the fourth hard mask layer 418 and the third hard mask layer 416, a better pattern migration effect is achieved, and the pattern will be more accurate, such that the reliability and integrity of the semiconductor structure may be enhanced.

As shown in FIGS. 2B, 4B, and 4C, in operation 224c, the third hard mask stack 440 is formed in the first trenches 432 and on the second hard mask stack 430 and the photoresist (not shown) is formed on the third hard mask stack 440, followed by the patterning of the photoresist to form a photoresist 450 and a second opening 456 extending along a fourth direction (not shown) different from the third direction. In some embodiments, the number of the second opening 456 can be more than one, e.g. two, three, four, five, etc. In some embodiments, the third hard mask stack 440 includes a first hard mask layer 442, a second hard mask layer 444, a third hard mask layer 446, and a fourth hard mask layer 448. In some embodiments, the photoresist 450 includes an anti-reflection structure 452 and a photoresist layer 454. Please refer to the aforementioned embodiments of the first hard mask layer 412, the second hard mask layer 414, the third hard mask layer 416, the fourth hard mask layer 418, the photoresist 420, the anti-reflection structure 422, and the photoresist layer 424 for the embodiments of the first hard mask layer 442, the second hard mask layer 444, the third hard mask layer 446, the fourth hard mask layer 448, the photoresist 450, the anti-reflection structure 452, and the photoresist layer 454. In some embodiments, the second hard mask layer 444 includes a silicon-rich DARC layer having a silicon content of 60 atomic % to 80 atomic %, such as 60, 62, 64, 66, 68, 70, 72, 74, 76, 78, or 80 atomic %. In some embodiments, the fourth hard mask layer 448 includes an oxide-rich DARC layer having an oxide content of 15 atomic % to 30 atomic %, such as 15, 16, 17, 18, 19, 20, 21, 22, 23, 24, 25, 26, 27, 28, 29, or 30 atomic %. Please refer to the aforementioned advantages of the fourth hard mask layer 418 for the advantages of the second hard mask layer 444 and the fourth hard mask layer 448.

As shown in FIGS. 2B, 4C, and 4D, in operation 224d, the third hard mask stack 440 and the photoresist 450 exposed from the second opening 456 are etched to form a second trench 462 extending along a fourth direction (not shown) different from the third direction, in which the second trench 462 is in the second hard mask stack 460. In some embodiments, the second hard mask stack 460 includes the first hard mask layer 412 and a second hard mask layer 458. In some embodiments, the second trench 462 is in the second hard mask layer 458. Please refer to the embodiments of the etching process of operation 224b for the embodiments of the etching process of the operation 224d. Due to the second hard mask layer 444 including a silicon-rich DARC having an silicon content of 60 atomic % to 80 atomic %, the etching selectivity between the second hard mask layer 444 and the first hard mask layer 442 enhance, comparing to the second hard mask layer 314 and the first hard mask layer 312. This causes during the etching process of the second hard mask layer 444 and the first hard mask layer 442, a better pattern migration effect may be achieved, and the pattern will be more accurate, such that the reliability and integrity of the semiconductor structure may be enhanced. Similarly, due to the fourth hard mask layer 448 including an oxide-rich DARC having an oxide content of 15 atomic % to 30 atomic %, the etching selectivity between the fourth hard mask layer 448 and the third hard mask layer 446 enhance, comparing to the fourth hard mask layer 318 and the third hard mask layer 316. This causes during the etching process of the fourth hard mask layer 448 and the third hard mask layer 446, a better pattern migration effect may be achieved, and the pattern will be more accurate, such that the reliability and integrity of the semiconductor structure may be enhanced.

As shown in FIGS. 2B, 4D, and 4E, in operation 224e, the second hard mask stack 460 and the dielectric layer 370 directly below the first trenches 432 and the second trench 462 are etched to form a first hard mask layer 464, a dielectric layer 110, and holes 466 and to remove a portion of the second hard mask stack 460. In some embodiments, a portion of the second hard mask stack 460 is referred to the second hard mask layer 458. In some embodiments, the second hard mask stack 460 and the dielectric layer 370 directly below the first trenches 432 and the second trench 462 are etched by the dry etching process. As shown in FIGS. 2B, 4D, and 4F, in operation 224f, the remaining portion of the second hard mask stack 460 is removed to form the dielectric layer 110 with the second through-holes 468 and the first through-holes 372. In some embodiments, the remaining portion of the second hard mask stack 460 is removed by dry etching process, in which the gas used in the dry etching process is O₂. In some embodiments, the first hard mask layer 464 is removed to form the dielectric layer 110 with the second through-holes 468 and the first through-holes 372. The first hard mask layer 464 has a high etching selectivity with respect to the dielectric layer 110, which may easily remove the first hard mask layer 464 without damaging the dielectric layer 110, such that the reliability and integrity of the semiconductor structure may be enhanced.

Refer to FIGS. 2A, 4F, 5A, and 5B, in operation 227a, the second landing pads 130 are formed in the second through-holes 468. In operation 227b, the first landing pads 120 are formed in the first through-holes 372, as shown in FIGS. 2A, 4F, 5A, and 5B. In some embodiments, forming the first landing pads 120 in the first through-holes 372 and forming the second landing pads 130 in the second through-holes 468 are performed simultaneously, as shown in FIGS. 5A-5B. In some embodiments, forming the first landing pads 120 in the first through-holes 372 and forming the second landing pads 130 in the second through-holes 468 are to form a semiconductor structure 500. In some embodiments, forming the first landing pads 120 in the first through-holes 372 and forming the second landing pads 130 in the second through-holes 468 include the following operations. A metal layer 502 is deposited in the first through-holes 372 and the second through-holes 468 and on the dielectric layer 110, as shown in FIGS. 4F and 5A. The metal layer 502 is planarized to form the first landing pads 120 in the first through-holes 372 and the second landing pads 130 in the second through-holes 468, as shown in FIGS. 4F-5B. In some embodiments, the metal layer 502 is deposited by, for example and without limitation, CVD process, PVD process, ALD process, sputtering, LPCVD process, another deposition process, or any suitable combination thereof. In some embodiments, the metal layer 502 is planarized by chemical mechanical polishing (CMP) process. The metal layer 502 planarized by CMP may reduce the step height of the array region AR and the periphery region PR of the dielectric layer 110, such that the reliability and integrity of the semiconductor structure may be enhanced, in which the formation of the step height is due to the difference in etching amount between the layers above the array region AR and the periphery region PR of the dielectric layer caused by different pattern densities during the forming process of the semiconductor structure 500. It is noted that the semiconductor structure 500 is formed by the damascene process.

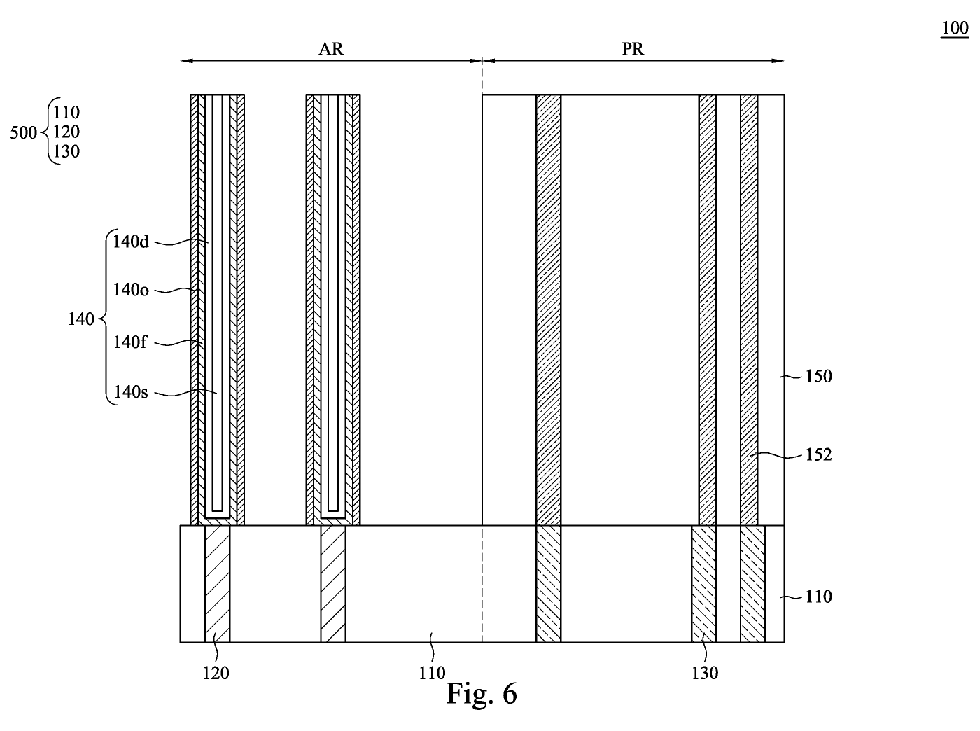

FIG. 6 is a cross-sectional view of the semiconductor structure 100. As shown in FIGS. 5B and 6, after the first landing pads 120 are formed in the first through-holes 372 (operation 227b), capacitor structures 140 are formed on the first landing pads 120, as shown in FIGS. 4F-6. In some embodiments, forming the capacitor structures 140 include the operations. As shown in FIG. 6, a stack structure (not shown) with holes (not shown) are formed on the semiconductor structure 500, in which the holes expose every first landing pads 120 and the stack structure includes a plurality of layers (not shown) having oxide layers and nitride layers, and a photoresist (not shown) on the layers. Please refer to the aforementioned formation of the dielectric layer 370 with the first through-holes 372 for the formation of the stack structure with the holes. In some embodiments, the photoresist includes bi-layer or tri-layer photoresist, such as the photoresists 340, 420, and 450. As shown in FIG. 6, the first electrode layers 140f are conformally formed on the holes, followed by the etching process of the stack structure with holes to remove the stack structure. In some embodiments, the etching process includes wet etching process. As shown in FIG. 6, the capacitor dielectric layers 140d are formed conformally on the inner sidewall and the bottom of the first electrode layers 140f and the outer dielectric layers 140o are formed on the outer sidewall of the first electrode layers 140f. As shown in FIG. 6, the second electrode layers 140s are formed in the capacitor dielectric layers 140d inside the first electrode layers 140f.

As shown in FIG. 6, a dielectric layer 150 with holes (not shown) formed above the periphery region PR of the semiconductor structure 500, in which a portion of the holes expose the second landing pads 130. Please refer to the aforementioned formation of the dielectric layer 110 with the second through-holes 468 for the formation of the dielectric layer 150 with the holes. As shown in FIG. 6, the conductive lines 152 are formed in the holes. Please refer to the formation of the first landing pads 120 and the second landing pads 130 for the formation of the conductive lines 152. In some embodiments, the capacitor structures 140, the dielectric layer 150, and the conductive lines 152 are formed by, for example and without limitation, CVD process, PVD process, ALD process, sputtering, LPCVD process, another deposition process, or any suitable combination thereof.

In summary, the present disclosure provides a forming method of the semiconductor structure. The forming method of the semiconductor structure includes forming the hard mask stack on the dielectric layer to act as a mask for the subsequent etching process of the dielectric layer. The hard mask stack includes different etching selectivity between the layers, which results in a better pattern migration effect, thus the pattern formed in the dielectric layer will be more accurate. Besides, the damascene process is performed in the formation of the semiconductor structure having the dielectric layer and the landing pads embedded in the dielectric layer, which causes the step height of the array region and the periphery region of the dielectric layer decrease. Thus, the foregoing features enhance the reliability and integrity of the semiconductor structure.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A method of forming a semiconductor structure, comprising:
forming a first hard mask stack on a dielectric layer, wherein the first hard mask stack comprises a plurality of carbon layers and a plurality of anti-reflection coating layers that are alternatively stacked, and the dielectric layer comprises an array region;
etching the first hard mask stack to form a second hard mask stack and a first trench extending along a first direction above the array region and in the second hard mask stack, wherein a bottom surface of the first trench is in one of the anti-reflection coating layers;
forming a photoresist on the second hard mask stack and in the first trench;
etching the photoresist and the second hard mask stack to form a second trench extending along a second direction different from the first direction, wherein the first trench and the second trench cross each other to form an intersection;
removing the photoresist;
etching the second hard mask stack directly below the intersection to form a hole to expose the dielectric layer;
etching the dielectric layer exposed from the hole to form a first through-hole; and
forming a first landing pad in the first through-hole.

2. The method of claim 1, wherein a k value of the dielectric layer is less than or equal to 4.

3. The method of claim 1, wherein forming the first hard mask stack on the dielectric layer comprises sequentially depositing a first carbon layer, a first anti-reflection coating layer, a second carbon layer, and a second anti-reflection coating layer on the dielectric layer.

4. The method of claim 3, wherein the bottom surface of the first trench is in the first anti-reflection coating layer.

5. The method of claim 1, wherein forming the photoresist on the second hard mask stack and in the first trench comprises sequentially depositing a photoresist underlayer, an anti-reflection structure, and a photoresist layer on the second hard mask stack and in the first trench.

6. The method of claim 1, wherein an angle between the first direction and the second direction is between 60 degrees to 120 degrees.

7. The method of claim 1, wherein forming the first landing pad in the first through-hole comprises:
depositing a metal layer in the first through-hole and on the dielectric layer; and
planarizing the metal layer to form the first landing pad in the first through-hole.

8. The method of claim 1, further comprising:
after forming the first landing pad in the first through-hole, forming a capacitor structure on the first landing pad.

9. The method of claim 1, after etching the dielectric layer exposed from the hole to form the first through-hole, further comprising:
etching a periphery region of the dielectric layer to form an second through-hole; and
forming a second landing pad in the second through-hole.

10. The method of claim 9, wherein forming the first landing pad in the first through-hole and forming the second landing pad in the second through-hole are performed simultaneously.

11. A method of forming a semiconductor structure, comprising:
sequentially depositing a first hard mask layer, a second hard mask layer, a third hard mask layer, and a fourth hard mask layer on a dielectric layer, wherein the first hard mask layer and the third hard mask layer have a high etching selectivity with respect to the second hard mask layer and the fourth hard mask layer, and the dielectric layer comprises an array region;
etching the second hard mask layer, the third hard mask layer, and the fourth hard mask layer to form a first trench extending along a first direction above the array region and to remove the third hard mask layer and the fourth hard mask layer;
forming a second trench in the second hard mask layer extending along a second direction different from the first direction, wherein the first trench and the second trench cross each other to form an intersection and to expose the first hard mask layer;
forming a first through-hole penetrating the first hard mask layer and the dielectric layer below the intersection;
removing the first hard mask layer and the second hard mask layer; and
forming a first landing pad in the first through-hole.

12. The method of claim 11, wherein the first hard mask layer and the third hard mask layer are carbon layers, and the second hard mask layer and the fourth hard mask layer are anti-reflection coating layers.

13. The method of claim 11, further comprising:
after forming the first landing pad in the first through-hole, forming a capacitor structure on the first landing pad.

14. The method of claim 11, wherein before etching the second hard mask layer, the third hard mask layer, and the fourth hard mask layer to form the first trench extending along the first direction above the array region and to remove the third hard mask layer and the fourth hard mask layer, further comprising:
forming a patterned photoresist layer with a first opening on the fourth hard mask layer and to expose the fourth hard mask layer;
conformally forming a spacer layer to cover the patterned photoresist layer and in the first opening; and
etching a horizontal portion of the spacer layer to expose the patterned photoresist layer and the fourth hard mask layer.

15. The method of claim 11, after removing the first hard mask layer and the second hard mask layer, further comprising:
etching a periphery region of the dielectric layer to form a second through-hole; and
forming a second landing pad in the second through-hole.
